(19) United States
(12) Patent Application Publication
(10) Pub. No.: US 2021/0372576 A1
(43) Pub. Date: Dec. 2, 2021

(54) METHOD FOR MANUFACTURING A LIGHT-EMITTING APPARATUS

(71) Applicant: TOP INTERNATIONAL ENTERPRISE LIMITED, Mongkok (HK)

(72) Inventor: Giedrius SRUOGIS, New Territories (HK)

(73) Assignee: TOP INTERNATIONAL ENTERPRISE LIMITED, Mongkok (HK)

(21) Appl. No.: 17/091,443

(22) Filed: Nov. 6, 2020

(30) Foreign Application Priority Data
May 29, 2020 (CN) 202010472047.3

(51) Int. Cl. F21K 9/90; F21K 9/69; F21V 23/00; B29D 11/00; B29C 45/14

(52) U.S. Cl. CPC F21K 9/90; F21K 9/69; F21Y 2115/10; B29D 11/00567; B29C 45/14008; F21V 23/005

(57) ABSTRACT

The present disclosure relates to a method for manufacturing a light-emitting apparatus, comprising carrying out a first injection molding process around each of a plurality of light sources disposed on a circuit board to form a lens holder surrounding the light source; and disposing a lens in the lens holder to form the light-emitting apparatus capable of emitting light when the circuit board is energized. In accordance with the method of the present disclosure, installation accuracy and precision of lenses can be effectively ensured, and requirements on thickness and hardness of a circuit board can be reduced.

### TECHNICAL FIELD

The present disclosure generally relates to the manufacturing field. In particular, the present disclosure relates to a method for manufacturing a light-emitting apparatus.

### BACKGROUND

In our daily life, lighting apparatuses have been widely used. In the manufacturing process of the light-emitting apparatuses, some components need to be fixed on a circuit board. For instance, to meet requirements on different light emitting angles or changing light emitting angles, a lens is typically installed and then aligned with a light source. A commonly-used installation method is to dispose and fix the lens on a circuit board by gluing, clamping or screw fastening. However, the gluing manner suffers insufficiency in precision and accuracy and thus is hard to ensure relative positions of the lens and the light source, which will influence the optical effect of the light-emitting apparatus. The manners of clamping or screw fastening requires the circuit board to have certain hardness and thickness, which is thus not applicable to a flexible printed circuit or a thin circuit board and cannot meet the requirement on thinning of the flexible printed circuits.

### SUMMARY

As to the above-mentioned technical problems, the technical solution of the present disclosure provides a method for manufacturing a light-emitting apparatus, comprising carrying out a first injection molding process around each of a plurality of light sources disposed on a circuit board to form a lens holder surrounding the light source; and disposing a lens in the lens holder to form the light-emitting apparatus capable of emitting light when the circuit board is energized.

In accordance with one embodiment of the present disclosure, the step of disposing a lens in the lens holder comprises carrying out a second injection molding process on an interior space of the lens holder to form the lens surrounding the light source.

In accordance with another embodiment of the present disclosure, prior to the step of carrying out a first injection molding process, the method further comprises disposing a light source cover on the circuit board for covering each light source, wherein a space exists between the light source cover and the light source so as to form a first air gap.

In accordance with yet another embodiment of the present disclosure, the step of disposing the lens in the lens holder comprises inserting and fixing the lens adaptive to the shape of an inner surface of the lens holder into the lens holder.

In accordance with one embodiment of the present disclosure, the step of fixing the lens into the lens holder comprises fixing the lens into the lens holder by clamping.

In accordance with another embodiment of the present disclosure, the step of carrying out a first injection molding process to form the lens holder further comprises, during carrying out the first injection molding process, forming, on one side of the inner surface of the lens holder near the light source, an inner edge suitable for being clamped with the lens.

In accordance with yet another embodiment of the present disclosure, the inner edge comprises an annular convex part for being clamped with the lens, and the bottom of the lens has an annular concave part for being clamped with the annular convex part.

In accordance with one embodiment of the present disclosure, the incident surface of the lens has a curved structure or a flat structure covering the light source, and when the lens is fixed into the lens holder, a space exists between the incident surface and the light source so as to form a second air gap.

In accordance with another embodiment of the present disclosure, prior to the step of carrying out a first injection molding process, the method further comprises applying an adhesive, punching a hole or forming a slot on the circuit board where the first injection molding process is carried out, so as to further fix the lens holder.

In accordance with yet another embodiment of the present disclosure, the plurality of light sources are a plurality of LED lights regularly arrayed on the circuit board, and the circuit board is a flexible printed circuit or a printed circuit board.

In accordance with one embodiment of the present disclosure, the method further comprises installing a housing on the outside of the light-emitting apparatus for encapsulating the light-emitting apparatus.

By describing the technical solution and embodiments of the present disclosure, those skilled in the art should understand that, in accordance with the method for manufacturing a light-emitting apparatus provided by the present disclosure, a lens holder fixed on a circuit board is formed through carrying out a first injection molding process around each light source, and installation accuracy and precision of the lens are effectively ensured through defining the position where the lens is located via the lens holder. Besides, the lens holder and other components are fixed through an injection molding process, such that requirements on thickness and hardness of the circuit board are reduced. Hence, this method is applicable to a flexible printed circuit, a thin circuit board and the like, thereby meeting the developing requirements on thinning of flexible printed circuits and other circuit boards.

### BRIEF DESCRIPTION OF THE DRAWINGS

The above and other objects, features and advantages of the illustrative embodiments of the present disclosure will be easily understood from the following detailed description taken in conjunction with the accompanying drawings. In the drawings, a few of embodiments are shown in an illustrative rather than a restrictive way, and same or corresponding reference signs represent the same or corresponding components, in which

FIG. 1 generally shows a flow diagram of a method for manufacturing a light-emitting apparatus in accordance with the present disclosure;

FIG. 2 shows a flow diagram of the method comprising a second injection molding process in accordance with embodiments of the present disclosure;

FIG. 3 shows a schematic diagram of a specific implementing process of the method as shown in FIG. 2;

FIG. 4 shows a flow diagram of the method comprising disposing a light source cover in accordance with embodiments of the present disclosure;

FIG. 5 shows a schematic diagram of a specific implementing process of the method as shown in FIG. 4;

FIG. 6 shows a flow diagram of the method comprising inserting a lens in accordance with embodiments of the present disclosure;

FIG. 7 shows a schematic diagram of a specific implementing process of the method as shown in FIG. 6;

FIG. 8 shows a flow diagram of the method comprising installing a housing in accordance with embodiments of the present disclosure; and

FIGS. 9a and 9b show multiple schematic diagrams of applied embodiments of the method as shown in FIG. 8.

### DETAILED DESCRIPTION OF THE EMBODIMENTS

There will provide a clear and complete description about the technical solutions in embodiments of the present disclosure with reference to the accompanying drawings therein. Apparently, the described embodiments are merely a portion of, not all of, the embodiments of the present disclosure. Based on these embodiments of the present disclosure, all other embodiments accessible to those skilled in the art without paying any creative effect shall fall into the protection scope of the present disclosure.

It should be understood that, the terms “first”, “second”, “third”, “fourth” and the like in the claims, the description and the accompanying drawings of the present disclosure merely serve for the purpose of distinguishing different objects, instead of defining a specific sequence. The wordings “include” and “comprise” used in the description and claims of the present disclosure indicate existence of the described features, entireties, steps, operations, elements and/or components, but do not intend to exclude existence or addition of one or more other features, entireties, steps, operations, elements, components, and/or a combination thereof.

It also should be understood that, the terms used in the description of the present disclosure are merely descriptive, rather than restrictive to the particular embodiments of the present disclosure. As used in the description and claims of the present disclosure, unless otherwise mentioned, the singular forms “one”, “a” and “the” comprise plural meanings. It should be further understood that, the term “and/or” used in the description and claims refers to one or any combination and all possible combinations of more associated items that are listed and comprises these combinations.

As used in the description and claims of the present disclosure, the term “if” can be interpreted as “when” or “once”, or “in response to determining” or “in response to detecting” in accordance with the context. Similarly, the phrase “if determining” or “if detecting the described condition or event” can be interpreted as “once determining” or “in response to determining” or “once detecting the described condition or event” or “in response to detecting the described condition or event” in accordance with the context.

As far as the drawbacks of the prior art, the present disclosure provides a brand-new feasible solution. In particular, in accordance with the method for manufacturing a light-emitting apparatus provided by the present disclosure, a lens holder fixed on a circuit board is formed by carrying out an injection molding process around each light source, and installation accuracy and precision of the lens are effectively ensured by defining the position where the lens is located via the lens holder. From the description below, those skilled in the art should understand that, the present disclosure also provides more embodiments to achieve deployment of the lens. For instance, the lens is formed by carrying out a second injection molding process. Or the lens is inserted and fixed into the lens holder, and the like. The particular embodiments of the present disclosure will be explained in detail with reference to the accompanying drawings.

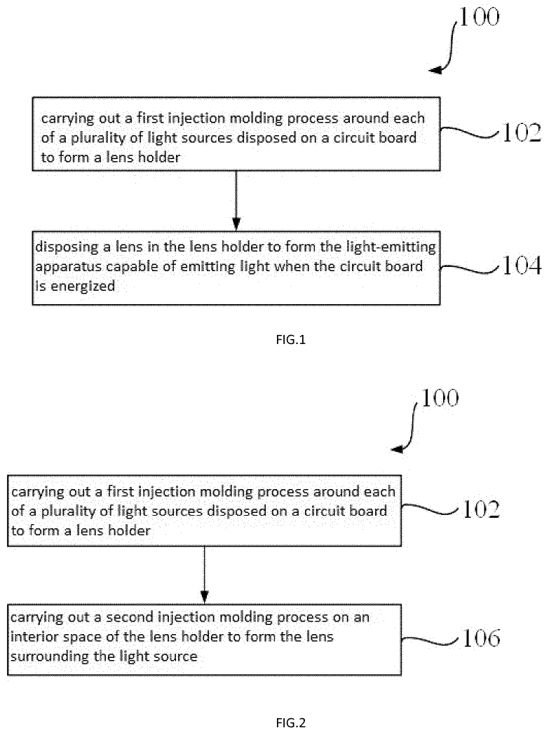

FIG. 1 generally shows a flow diagram of a method 100 for manufacturing a light-emitting apparatus in accordance with the present disclosure. As shown in FIG. 1, in step 102, the method 100 comprises carrying out a first injection molding process around each of a plurality of light sources disposed on a circuit board to form a lens holder surrounding the light source. In one embodiment, the method 100 may comprise carrying out a first injection molding process around a light source which serves as the center to form a lens holder fixed on a circuit board.

The above-mentioned first injection molding process may be a process of carrying out injection molding in a mould of which the shape and dimension are set as required. The injection molding material used in the first injection molding process may be selected from at least one of silica gel, nylon, ethylene-vinyl acetate copolymer (EVA), thermoplastic polyurethanes (TPU) and the like. The lens holder formed by the method 100 in accordance with the present disclosure can be prepared to be transparent or non-transparent as required. A non-transparent lens holder has a reflection effect. In one embodiment, the lens holder is white but non-transparent.

In accordance with the method 100 of the present disclosure, the lens holder fixed on a circuit board is formed by injection molding so as to improve installation accuracy and precision of the lens holder and reduce requirements on thickness and hardness of the circuit board. For instance, in one embodiment, the circuit board may be a flexible printed circuit (FPC) or printed circuit board (PCB). The circuit board is a one-side circuit board or a two-side circuit board. For instance, in another embodiment, the circuit board is a two-side circuit board, and the method 100 comprises carrying out a first injection molding process around each of a plurality of light sources disposed on the front and reverse faces of a circuit board.

The above light source may be a light-emitting component, such as a mini incandescent lamp, a fluorescent lamp or a light-emitting diode (LED). The plurality of light sources are regularly or irregularly disposed on the circuit board. For example, in one embodiment, the plurality of light sources are a plurality of LED lights regularly disposed on the circuit board. In another embodiment, the plurality of light sources are in different types. The method 100 may comprise carrying out a first injection molding process around each of a plurality of light sources of different types disposed on the circuit board.

Further, in accordance with one embodiment of the present disclosure, prior to carrying out the first injection molding process, the method 100 further comprises: applying an adhesive, punching a hole or forming a slot on the circuit board where the first injection molding process is carried out, so as to further fix the lens holder. In the operation of punching a hole or forming a slot on the circuit board of the method 100, an injection molding material is poured into the hole or slot of the circuit board during the first injection molding process so that the lens holder and the circuit board are clamped. Due to this arrangement, firmness of connection between the lens holder and the circuit board is further enhanced.

Next, in step 104, the method 100 also comprises disposing a lens in the lens holder to form the light-emitting apparatus capable of emitting light when the circuit board is energized. By first forming the lens holder and then disposing the lens in the method 100, the lens holder plays a role in limiting the shape or position of the lens, thereby ensuring that the lens is disposed accurately and preciously relative to the light source to further ensure the optical effect of the light-emitting apparatus. In the method 100, a lens may be disposed in the lens holder through many ways, for instance, in one embodiment, the method 100 comprises carrying out a second injection molding process to form the lens. In another embodiment, the method 100 comprises inserting the lens adaptive to the shape of an inner surface of the lens holder into the lens holder. To make those skilled in the art further understand the technical solution of the present disclosure, a specific description will be given below in combination with more embodiments.

FIG. 2 shows a flow diagram of the method comprising a second injection molding process in accordance with embodiments of the present disclosure. It is understood that, the method 100 shown in FIG. 2 embodies the method depicted in the preceding text with reference to FIG. 1.

As shown in FIG. 2, in step 102, the method 100 comprises carrying out a first injection molding process around each of a plurality of light sources disposed on a circuit board to form a lens holder surrounding the light source. Step 102 has been described in detail in the preceding text with reference to FIG. 1 and thus will not be repeated any more.

Next, in step 106, the method 100 comprises carrying out a second injection molding process on an interior space of the lens holder to form the lens surrounding the light source. It should be noted that, step 106 is an embodiment of step 104 as shown in FIG. 1 in which the lens is disposed in the lens holder. The second injection molding process may be carried out directly on the interior space of the lens holder or in a mould disposed on the lens holder. In one embodiment, the step of carrying out a second injection molding process of method 100 is to perform injection molding in an interior space of the lens holder and meanwhile form an emitting surface of the lens via injection molding of the mould. The lens manufactured by the second injection molding process wraps the light source or has a space with the light source. The step of carrying out a second injection process of the method 100 is performed at the temperature that should be lower than that bearable by the light source.

Further, in accordance with one embodiment of the present disclosure, prior to carrying out a second injection molding process, the method 100 further comprises applying an adhesive, punching a hole or forming a slot on the circuit board where the second injection molding process is carried out, so as to further fix the lens holder. In the operation of punching a hole or forming a slot on the circuit board of the method 100, an injection molding material is poured into the hole or slot of the circuit board during the second injection molding process so that the lens and the circuit board are clamped. Due to this arrangement, firmness of connection between the lens and the circuit board is further enhanced.

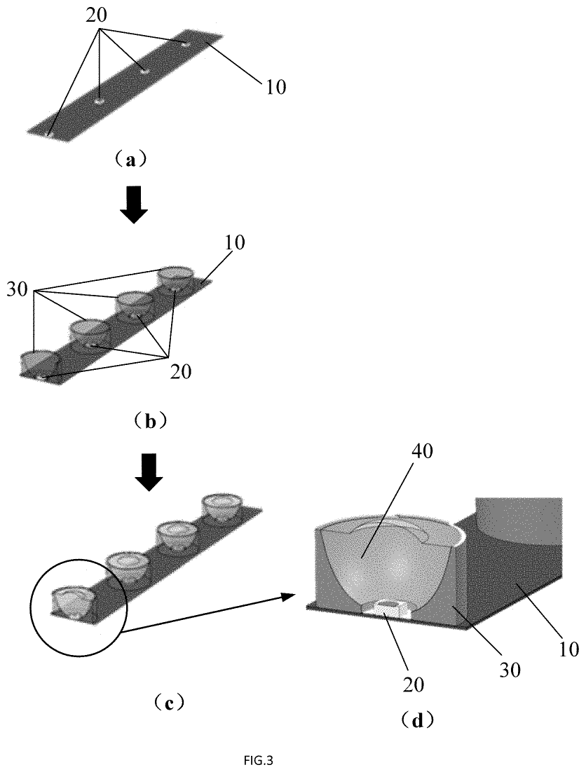

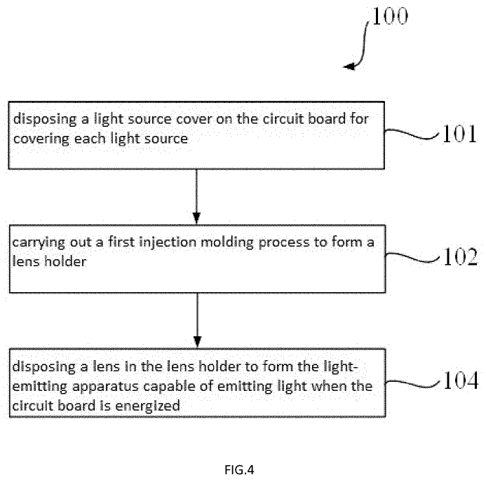

The above described the method comprising disposing the lens through injection molding with reference to FIG. 2. From the description, those skilled in the art should be understood that, the lens formed by carrying out the second injection molding process well clings to the inner surface of the lens holder, and the bottom of the lens is fixed on the circuit board, thereby improving stability and firmness of the lens. For easy understanding of those skilled in the art to the embodiment, the method as shown in FIG. 2 will be further described with reference to the embodiment of FIG. 3.

FIG. 3 visually shows an embodiment of the method 100 in FIG. 2. As shown in FIG. 3, FIG. 3(a) shows a circuit board 10 and a plurality of light sources 20 disposed on the circuit board 10. The plurality of light sources 20 are regularly disposed on the circuit board 10 at intervals. FIG. 3(b) shows a semi-product of the light-emitting apparatus having the lens holder 30, formed after carrying out step 102 in the method 100. That is to say, the method 100 comprises carrying out a first injection molding process around each of a plurality of light sources 20 disposed on a circuit board 10 to form a lens holder 30. For instance, each of four light sources 20 has a lens holder 30 at its periphery in the figure.

Then, the flow proceeds to FIG. 3(c). The light-emitting apparatus in the figure is formed by carrying out the second injection molding process on the interior space of the lens holder 30 in the method 100 (i.e., step 106 in FIG. 2). For conveniently observing the structures of the light-emitting apparatuses formed by twice injection molding, FIG. 3(d) is an enlarged sectional view of FIG. 3(c). In the figure, the lens 40 formed by the second injection molding wraps the light source 20, and the bottom of the lens 40 and the circuit board 10 are fixed together. The inner shape of the lens 40 is defined by the lens holder 30, and the emitting surface of the lens 40 is also formed by the second injection molding process.

The above is description about the embodiment of the lens formed by injection molding in accordance with the present disclosure with reference to FIGS. 2 and 3. It should be understood by those skilled in the art that, the apparatus in the figure and the above description are illustrative, rather than restrictive, and those skilled in the art can make adjustment as required. For instance, the quantity of the light sources is not limited to four as shown in FIG. 3, and more or less light sources may be disposed as required. The shape of the lens holder and the shape of the lens are not limited to those shown in the figures, and the shapes can be adjusted as required. The way that the lens surrounds the light source is not limited to closely wrapping as shown in the figure, and there may have a space between the lens and the light source.

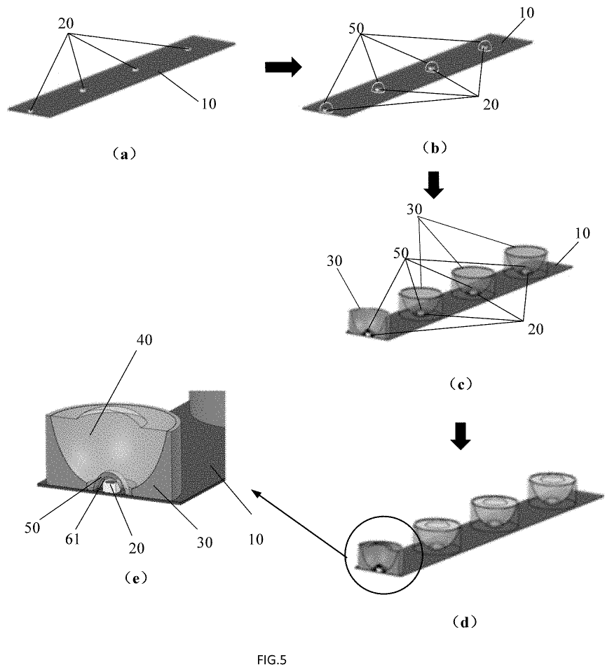

FIG. 4 shows a flow diagram of the method comprising disposing a light source cover in accordance with embodiments of the present disclosure. As shown in FIG. 4, in step 101, the method 100 comprises disposing a light source cover on the circuit board for covering each light source, wherein a space exists between the light source cover and the light source so as to form a first air gap. The light source cover is disposed by taking the light source as the center. The light source cover is fixed on the circuit board. In one embodiment, the method 100 comprises fixing the light source cover on the circuit board via glue and smearing the glue on the circuit board through spraying, silk screen or potting via a potting machine. In another embodiment, the method 100 comprises fixing the light source cover on the circuit board through a surface mounting technology (SMT), and the light source cover can be assembled by using a standard pasting machine.

In accordance with the present disclosure, the shape of the light source cover may be in the shape of an arch, a hemisphere, a semiellipsoid, a square, a cylinder or the like. The light source cover is made from plastics, rubber, silica gel or the like. The light source cover is set to be transparent or semi-transparent as required. For instance, in some scenes requiring beam narrowing or collimation, the light source cover is set to be transparent. For instance, for the purpose of diffusion or color mixing, the light source cover is set to be semi-transparent.

In further description of step 101, there is a space between the light source cover and the light source so as to form a first air gap. The first air gap on the surface of the light source gives more design flexibility on changing optical properties. In accordance with this arrangement, incident light from the light source is optically reflected by the first air gap before entering the lens so as to enhance optical effects such as a light condensing effect.

Next, in step 102, the method 100 comprises carrying out a first injection molding process around each light source cover so as to form a lens holder. This step is as same or similar to that described in step 102 with reference to FIGS. 1 and 2 and thus will not be repeated any more.

Then, in step 104, the method 100 comprises disposing a lens in the lens holder to form the light-emitting apparatus capable of emitting light when the circuit board is energized. In one embodiment, in the method 100, the step of disposing a lens in the lens holder comprises carrying out a second injection molding process on an interior space of the lens holder to form the lens surrounding the light source and the light source cover, wherein the lens wraps the light source cover but has no effect on formation of the first air gap. The second injection molding process has been described in detail in step 106 with reference to FIG. 2 and thus will not be repeated any more. The light source cover can protect the light source. Further, the light source cover can remove the limitations on conditions such as the temperature of the injection molding, as the influence to the light source from factors such as temperature and the like in the second injection molding process can be avoided.

The above is the illustrative description about the method comprising disposing a light source cover with reference to FIG. 4. To make those skilled in the art easily understand the method of the embodiment, the method will be further explained with reference to FIGS. 4 and 5. From the description below, it should be understood that the light-emitting apparatus manufacturing process shown in FIG. 5 embodies the method shown in FIG. 4. Therefore, the explanation about the method 100 is also applicable to the description below.

FIG. 5 shows a schematic diagram of a particular embodiment of the method 100 shown in FIG. 4. FIG. 5(a) illustratively shows a circuit board 10 and a plurality of light sources 20 disposed on the circuit board 10. The plurality of light sources 20 are regularly disposed on the circuit board 10 at intervals. Next, FIG. 5(b) visually shows the light source cover 50 disposed when carrying out step 101 of the method 100. That is, the method 100 of the present disclosure comprises disposing a light source cover 50 on the circuit board 10 for covering each light source 20. After the light source cover 50 is fixed on the circuit board 10, the method 100 comprises carrying out the first injection molding process to form a lens holder 30 surrounding each light source cover 50 shown in FIG. 5(c). That is, in step 102, the method 100 comprises carrying out a first injection molding process around each of a plurality of light sources 20 and the light source cover 50 disposed on a circuit board 10 to form a lens holder 30. For instance, each of four light source covers 50 in the figure has a lens holder 30 at its periphery.

Afterwards, the flow proceeds to FIG. 5(d). The method 100 comprises disposing a lens in the lens holder 30 formed in FIG. 5(c) to form the light-emitting apparatus capable of emitting light when the circuit board 10 is energized. The method of disposing a lens may, for example, adopt step 106 as shown in FIG. 2. That is, the method 100 comprises carrying out a second injection molding process on an interior space of the lens holder 30 to form the light-emitting apparatus shown in FIG. 5(d). For conveniently observing the structures of the light-emitting apparatus formed after disposing a light source cover, FIG. 5(e) is an enlarged sectional view of FIG. 5(d). In the figure, the lens 40 disposed in the light-emitting apparatus wraps the light source cover 50, and the bottom of the lens 40 and the circuit board 10 are fixed together. The inner shape of the lens 40 is defined by the lens holder 30, and the shape of the incident surface of the lens 40 is defined by the shape of the light source cover 50. The light source cover 50 wraps the light source 20, and there is a first air gap 61 between the light source cover 50 and the light source 20. Due to this arrangement, optical reflection is advantageously increased so as to improve optical properties of the light-emitting apparatus.

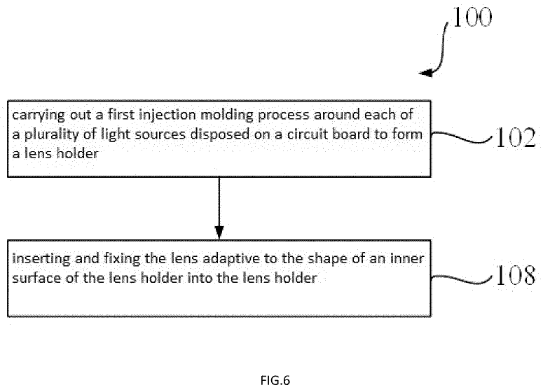

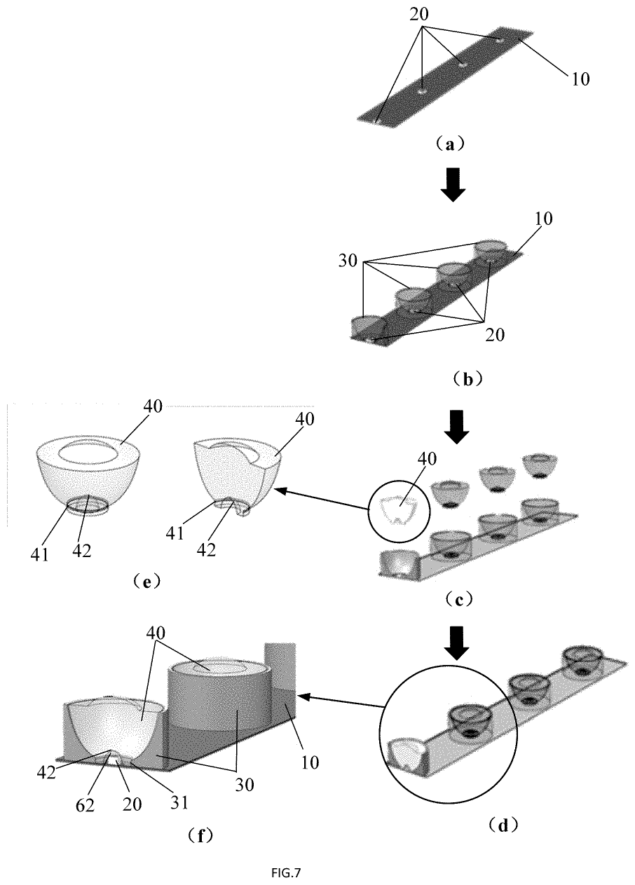

The above is description about the embodiment of the method comprising disposing a light source cover in accordance with the present disclosure with reference to FIGS. 4 and 5. It should be understood by those skilled in the art that, the apparatus in the figure and the above description are illustrative, rather than restrictive, and those skilled in the art can make adjustment as required. For instance, the quantity of the light sources is not limited to four as shown in FIG. 5, and more or less light sources may be disposed as required. The shape of the lens holder and the shape of the lens are not limited to those shown in the figure, and the shapes can be adjusted as required. The way of disposing a lens in the lens holder is not limited to injection molding and other ways may be adopted. An illustrative description will be given below with reference to FIGS. 6 and 7.

FIG. 6 shows a flow diagram of the method comprising inserting a lens in accordance with the present disclosure. As show in FIG. 6, at step 102, the method 100 comprises carrying out a first injection molding process around each of a plurality of light sources disposed on a circuit board to form a lens holder surrounding the light source. Step 102 has been described in detail in the preceding text with reference to several embodiments and will not be repeated any more.

Next, the flow proceeds to step 108. The method 100 comprises inserting the lens adaptive to the shape of an inner surface of the lens holder into the lens holder. It should be understood that, step 108 is an embodiment of step 104 described with reference to FIG. 1 as above, that is to say, step 108 is an embodiment of disposing a lens in a lens holder. In step 108, the lens may be a separate component manufactured in accordance with the shape of the inner surface of the lens holder to facilitate assembly when need. The separate component is convenient to store and install. In such a case, the lens and the lens holder are not restricted by temperature and other conditions during assembly, thereby having no effect on the light source.

As described in step 108, the method 100 comprises fixing the lens in the lens holder. Due to this arrangement, the lens is prevented from falling off or being lost, and thus the completeness and optical effects of the light-emitting apparatus are ensured. The lens can be fixed by many ways. For example, in accordance with one embodiment of the present disclosure, the step of fixing the lens into the lens holder comprised in the method 100 may comprise fixing the lens into the lens holder by sticking. For example, in the method 100, glue, an adhesive or the like may be used to stick the outer surface of the lens to the inner surface of the lens holder. In accordance with another embodiment of the present disclosure, the step of fixing the lens into the lens holder comprised in the method 100 may comprise fixing the lens into the lens holder by clamping. In this way, only a simple clamping operation is needed in inserting the lens in the lens holder in the method 100, so that the lens is fixed. Therefore, the operation is simple and convenient, and the assembly speed is improved, thereby enhancing the production efficiency.

The above clamping manner may be achieved in many forms. For example, in accordance with one embodiment of the present disclosure, in step 102, the step of carrying out a first injection molding process to form the lens holder comprised in the method 100 may further comprise: during carrying out the first injection molding process, forming, on one side of the inner surface of the lens holder near the light source, an inner edge suitable for being clamped with the lens. To be specific, in one embodiment, the inner edge comprises an annular convex part for being clamped with the lens, and the bottom of the lens has an annular concave part for being clamped with the annular convex part. In another embodiment, the inner edge comprises a plurality of convex parts for being clamped with the lens, and the lens also has a plurality of concave parts for being clamped with the plurality of convex parts at its corresponding locations.

The above describes another embodiment of disposing a lens in accordance with the method for manufacturing a light-emitting apparatus in the present disclosure in combination of FIG. 6. To facilitate those skilled in the art understanding the embodiment, further explanation will be given below with reference to FIGS. 6 and 7. From the description below, it is understood that, the manufacturing process of the light-emitting apparatus shown in FIG. 7 is an embodiment of the method in FIG. 6. Therefore, explanation about the method 100 is also applicable to the description below.

FIG. 7 shows a schematic diagram of a particular embodiment of the method 100 in FIG. 6. FIG. 7(a) illustratively shows a circuit board 10 and a plurality of light sources 20 disposed on the circuit board 10. The plurality of light sources 20 are regularly disposed on the circuit board 10 at intervals. Next, the method 100 comprises carrying out a first injection molding process around each of a plurality of light sources 20 disposed on a circuit board 10 as shown in FIG. 7(a) to form a lens holder 30 surrounding the light source 20 as shown in FIG. 7(b). For example, each of four light sources 20 has a lens holder 30 at its periphery in the figure.

Afterwards, as described in FIG. 7(c), the method 100 comprises inserting the lens adaptive to the shape of an inner surface of the lens holder into the lens holder. To facilitate the observation, FIG. 7(e) shows an enlarged sectional view and a complete view of the lens 40 in FIG. 7(c). In the figure, the shape of the lens 40 is adaptive to the shape of the inner surface of the lens holder 30. In one embodiment, the bottom of the lens 40 has an annular concave part 41 for being clamped with the lens holder 30. As further illustrated in FIG. 7(e), in accordance with one embodiment of the present disclosure, the incident surface 42 of the lens 40 has a curved structure covering the light source 20. It should be noted that, the structure of the incident surface of the lens 40 is not limited to the curved structure in the figure. For example, in another embodiment, the incident surface 42 of the lens 40 has a flat structure covering the light source 20.

Further, the flow proceeds to FIG. 7(d). The method 100 comprises inserting and fixing the lens 40 into the lens holder 30 to form a light-emitting apparatus. For convenience of observation and description, FIG. 7(f) shows an enlarged partial view of FIG. 7(d). In the figure, the lens holder 30 formed by the first injection molding process is fixed on the circuit board 10, and during carrying out the injection molding process, on one side of the inner surface of the lens holder 30 near the light source 20, an annular convex part 31 suitable for being clamped with the lens 40 is formed. The annular convex part 31 is clamped for fixation with the annular concave part 41 at the bottom of the lens 40. As further illustrated in FIG. 7(f), when the lens 40 is fixed in the lens holder 30, as the incident surface of the lens 40 has a curved structure, a space exists between the incident surface 42 and the light source 20 so as to form a second air gap 62. The second air gap on the surface of the light source 20 brings design flexibility for the purpose of changing optical properties. Due to this arrangement, incident light from the light source 20 is optically reflected by the second air gap 62 before entering in the lens 40, to enhance optical effects such as a light condensing effect.

The above describes another embodiment of the method comprising disposing a lens in accordance with the present disclosure with reference to FIGS. 6 and 7. It should be understood by those skilled in the art that, the apparatus in the figure and the above description are illustrative, rather than restrictive, and those skilled in the art can make any adjustment as required. For instance, the shape of the lens holder and the shape of the lens are not limited to those shown in the figures, and the shapes can be adjusted as required. In one embodiment, before inserting the lens in the lens holder, a light source cover may be disposed at first to protect the light source, and then the lens adaptive to the shape is inserted and fixed into the lens holder. The manner of clamping the lens with the lens holder is not limited to clamping between the annular concave part and the annular convex part, and other clamping ways may be adopted as required.

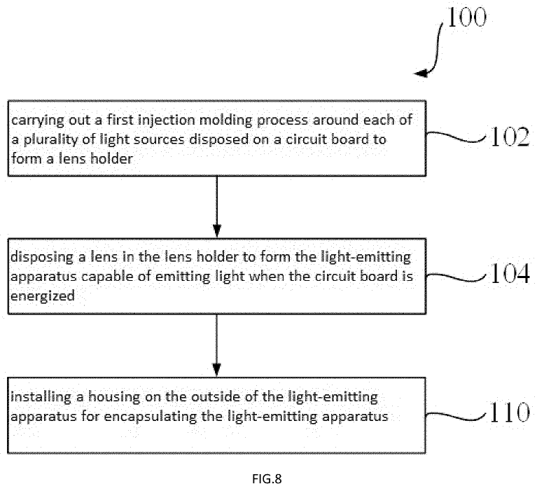

FIG. 8 shows a flow diagram of the method comprising installing a housing in accordance with embodiments of the present disclosure. As shown in FIG. 8, in step 102, the method 100 comprises carrying out a first injection molding process around each of a plurality of light sources disposed on a circuit board to form a lens holder surrounding the light source. Next, in step 104, the method 104 comprises disposing a lens in the lens holder to form the light-emitting apparatus capable of emitting light when the circuit board is energized. Step 102 and step 104 have been described in detail in the preceding text with reference to FIG. 1, and thus will not be repeated any more.

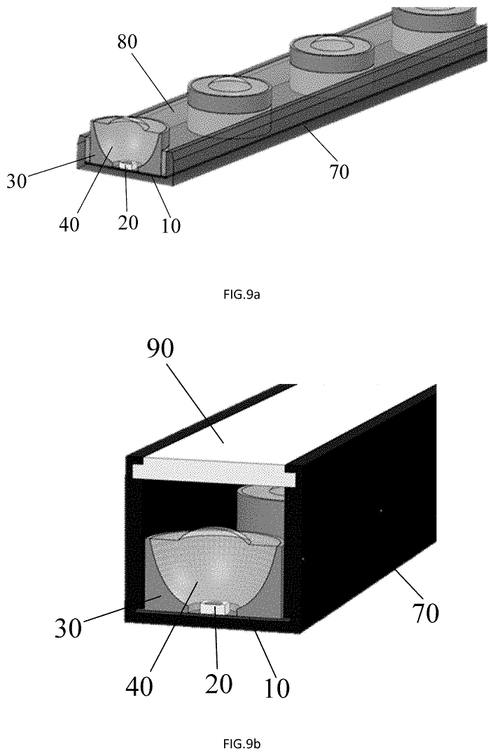

Further, in step 110, the method 100 comprises installing a housing on the outside of the light-emitting apparatus for encapsulating the light-emitting apparatus. Due to the encapsulation, components in the light-emitting apparatus are protected, the light-emitting apparatus looks pleasant and neat, and transport and use become easy. Installing a housing in the method 100 may be achieved in many forms of, for example, wrapping components in the light-emitting apparatus, having a space with the components in the light-emitting apparatus, or the like. An illustrative description will be given below with reference to embodiments of FIG. 9(a) and FIG. 9(b).

As shown in FIG. 9(a), the housing installed on the light-emitting apparatus comprises a tray 70 and an encapsulating layer 80 filled in the tray 70. The method 100 comprises inserting the circuit board 10 on which the light source 20, the lens holder 30 and the lens 40 are disposed in the tray 70, and filling the tray 70 with the encapsulating layer 80 so as to encapsulate the light-emitting apparatus. The tray 70 is made of metals, plastics, rubber and the like. The color of the tray 70 is set as required. Transparency of the tray 70 also can be set as required, e.g., it is set to be transparent or semi-transparent, or non-transparent. A non-transparent tray 70 plays a role in light reflection. In one embodiment, the encapsulating layer 80 is made of a potting compound and subjected to compound application via a potting machine.

As shown in FIG. 9(b), the housing installed on the light-emitting apparatus comprises a tray 70 and a cover plate 90 covering the top of the tray 70. The method 100 comprises inserting the circuit board 10 on which the light source 20, the lens holder 30 and the lens 40 are disposed in the tray 70, and inserting the cover plate 90 at the top of the tray 40 to encapsulate the light-emitting apparatus. The cover plate 90 is separated from components in the tray 70 such as the lens 40, and thus produces an effect of optical reflection. The material, color and the like of the tray 70 have been described in the preceding text with reference to FIG. 9(a), and thus will not be repeated any more. Heights of side plates at two sides of the tray 70 can be adjusted as required. The cover plate 90 is manufactured to be transparent or semi-transparent as required. The cover plate 90 is made of at least one of glass, polycarbonate, acrylonitrile butadiene styrene copolymers (i.e., ABS resin), polycarbonate (PC), polymethyl methacrylate (PMMA), polyvinyl chloride (PVC) and the like.

By describing the technical solution and more embodiments of the method for manufacturing a light-emitting apparatus in accordance with the present disclosure, those skilled in the art should understand that, through carrying out an injection molding process around each light source, a lens holder fixed on a circuit board is formed, and through defining the position where the lens is via the lens holder, installation accuracy and precision of the lens are effectively ensured. Besides, components like the lens holder are fixed through injection molding, requirements on thickness and hardness of the circuit board are reduced. Hence, this method meets the developing requirements on thinning of flexible printed circuits and other circuit boards.

Further, the present disclosure also discloses embodiments of disposing a lens in the lens holder, and those skilled in the art would choose them at will. For example, the method in the present disclosure comprises carrying out a second injection molding process to form a lens that well clings to the inner surface of the lens holder, and the lens is fixed on the circuit board through injection molding. The method of the present disclosure also comprises, for example, inserting and fixing a separately manufactured lens into the lens holder. Due to this arrangement, the lens is convenient and rapid to install, and the separately manufactured lens is controllable in shape, a particular shape or structure is manufactured as required, e.g., the lens is manufactured to have an incident surface having a curved structure or a flat structure to improve the optical effect of the light-emitting apparatus. Therefore, in accordance with the light-emitting apparatus manufactured by the method of the present disclosure, accuracy, precision, firmness and the like of the lens in installation are improved, limitations to the circuit board are reduced, optical effects of the light-emitting apparatus are perfected, and the application prospect is wide.

The described above is the embodiments of the present disclosure which merely serve for the purpose of easy understanding of the present disclosure, rather than placing limitations to scope and use scenes of the present disclosure. For those skilled in the art, any modifications and variations on forms and details of the embodiments can be made without departing from the spirit and scope of the present disclosure. But the attached claims of the present disclosure should prevail over the patent protection scope thereof.

1. A method for manufacturing a light-emitting apparatus, comprising:
carrying out a first injection molding process around each of a plurality of light sources disposed on a circuit board to form a lens holder surrounding the light source; and
disposing a lens in the lens holder to form the light-emitting apparatus capable of emitting light when the circuit board is energized.

2. The method of claim 1, wherein the step of disposing a lens in the lens holder comprises carrying out a second injection molding process on an interior space of the lens holder to form the lens surrounding the light source.

3. The method of claim 2, prior to the step of carrying out a first injection molding process, further comprising:
disposing a light source cover on the circuit board for covering each light source, wherein a space exists between the light source cover and the light source so as to form a first air gap.

4. The method of claim 1, wherein the step of disposing the lens in the lens holder comprises inserting and fixing the lens adaptive to the shape of an inner surface of the lens holder into the lens holder.

5. The method of claim 4, wherein the step of fixing the lens into the lens holder comprises fixing the lens into the lens holder by clamping.

6. The method of claim 5, wherein the step of carrying out a first injection molding process to form the lens holder further comprises:
during carrying out the first injection molding process, forming, on one side of the inner surface of the lens holder near the light source, an inner edge suitable for being clamped with the lens.

7. The method of claim 6, wherein the inner edge comprises an annular convex part for being clamped with the lens, and the bottom of the lens has an annular concave part for being clamped with the annular convex part.

8. The method of claim 4, wherein the incident surface of the lens has a curved structure or a flat structure covering the light source, and when the lens is fixed into the lens holder, a space exists between the incident surface and the light source so as to form a second air gap.

9. The method of claim 1, prior to the step of carrying out a first injection molding process, further comprising: applying an adhesive, punching a hole or forming a slot on the circuit board where the first injection molding process is carried out, so as to further fix the lens holder.

10. The method of claim 1, wherein the plurality of light sources are a plurality of LED lamps regularly arrayed on the circuit board, and the circuit board is a flexible circuit board or a printed circuit board.

11. The method of claim 10, further comprising:
installing a housing on the outside of the light-emitting apparatus for encapsulating the light-emitting apparatus.
